(19) United States
(12) Patent Application Publication
(10) Pub. No.: US 2026/0136671 A1
(43) Pub. Date: May 14, 2026

(54) DISPLAY PANEL AND DISPLAY DEVICE

(71) Applicant: Guangzhou China Star Optoelectronics Semiconductor Display Technology Co., LTd., Guangzhou (CN)

(72) Inventor: Lihong GUI, Guangzhou (CN)

(73) Assignee: Guangzhou China Star Optoelectronics Semiconductor Display Technology Co., LTd., Guangzhou (CN)

(21) Appl. No.: 19/195,629

(22) Filed: Apr. 30, 2025

(30) Foreign Application Priority Data
Nov. 14, 2024 (CN) 202411632647.6

(51) Int. Cl. H10D 86/40; G02F 1/1343; G02F 1/1362; G02F 1/1368; H10D 86/60

(52) U.S. Cl. CPC H10D 86/441; G02F 1/134309; G02F 1/136209; G02F 1/136286; G02F 1/1368; H10D 86/60

(57) ABSTRACT

The present application provides a display panel and a display device. The display panel includes a plurality of data line groups and a plurality of pixel electrode groups. Each of the data line groups includes a first data line and a second data line. Each of the pixel electrode groups includes a first pixel electrode and a second pixel electrode. The first data line is connected to the second pixel electrode of the first pixel row and the first pixel electrode of the second pixel row. The second data line is connected to the first pixel electrode of the first pixel row and the second pixel electrode of the second pixel row. A layout of the data line groups is adopted, so that an area of wirings in the first direction is reduced, thereby achieving the effect of improving an aperture ratio.

### CROSS-REFERENCE TO RELATED APPLICATION

This application claims priority to Chinese Patent Application Serial No. 202411632647.6 filed to China National Intellectual Property Administration (CNIPA) on Nov. 14, 2024, which is incorporated by reference in the present application with its entirety.

### TECHNICAL FIELD

The present application relates to the field of display technologies, and especially relates to a display panel, and a display device.

### BACKGROUND

Based on the contents disclosed in a patent document CN108628049B, data lines are designed in a rectangular wave shape due to an indentation amount between sub-pixel areas in adjacent rows and an alignment arrangement between sub-pixel areas in rows arranged at interval. Furthermore, since a data line is disposed between every two adjacent sub-pixel areas, a gap must be maintained between either side of the data line and pixel electrodes adjacent thereto, so that a wiring area of the data line is increased, thereby reducing an aperture ratio.

### SUMMARY

Embodiments of the present application provide a display panel and a display device to improve an aperture ratio.

Embodiments of the present application provides a display panel. The display panel includes an array substrate and an opposite substrate disposed opposite to the array substrate. The array substrate includes a plurality of scan lines, a plurality of data line groups, and a plurality of pixel electrode groups. The plurality of data line groups are arranged along a first direction. Each of the scan lines extends along the first direction. The plurality of scan lines are arranged along a second direction intersecting with the first direction. The plurality of scan lines intersect with the plurality of data line groups to define a plurality of pixel areas. Each of the pixel electrode groups is correspondingly disposed within one of the pixel areas, and the plurality of pixel electrode groups are arranged along the first direction to form pixel rows. The pixel rows includes a first pixel row and a second pixel row arranged along the second direction. Along the second direction, one of the pixel electrode groups of the first pixel row and one of the pixel electrode groups of the second pixel row are arranged in a stagger layout. Each of the data line groups includes a first data line and a second data line. Each of the pixel electrode groups includes a first pixel electrode and a second pixel electrode. The plurality of pixel electrode groups comprises a plurality of the first pixel electrodes and a plurality of the second pixel electrodes. Along the first direction, the first electrodes and the second pixel electrodes are arranged alternately, and the first data lines and the second data lines are arranged alternately. The first data line is connected to the second pixel electrode of the first pixel row and the first pixel electrode of the second pixel row, and the second data line is connected to the first pixel electrode of the first pixel row and the second pixel electrode of the second pixel row.

Accordingly, embodiments of the present application further provide a display device. The display device includes a display panel as described in anyone of the embodiments mentioned above.

In the display panel and display device of the embodiments of the present application, a layout of the data line groups is adopted, so that there is no data line between the first pixel electrode and the second pixel electrode of the pixel electrode group, thereby greatly reducing a distance between the first pixel electrode and the second pixel electrode in the pixel electrode group. Furthermore, although the data line is additionally provided between the pixel electrode groups, a distance between the first data line and the second data line is smaller, so that an area of wirings in the first direction is reduced, thereby achieving the effect of improving the aperture ratio.

### BRIEF DESCRIPTION OF THE DRAWINGS

FIG. 1 is a top plan view of a display panel provided by an embodiment of the present application.

FIG. 2 is a schematic cross-sectional structure of the display panel provided by the embodiment of the present application.

FIG. 3 is an enlarged schematic view of a portion M in FIG. 1.

FIG. 4 is a schematic structural view of a common electrode in FIG. 3.

FIG. 5 is a schematic view of a driving architecture of the display panel of one or more embodiments of the present application.

FIG. 6 is a structural view of a black matrix layer in FIG. 3.

FIG. 7 is another enlarged schematic view of the portion M in FIG. 1.

FIG. 8 is a structural view of a black matrix layer in FIG. 7.

FIG. 9 is yet another enlarged schematic view of the portion M in FIG. 1.

FIG. 10 is a structural view of a black matrix layer in FIG. 9.

FIG. 11 is still another enlarged schematic view of the portion M in FIG. 1.

FIG. 12 is a schematic structural view of a common electrode in FIG. 11.

FIG. 13 is a structural view of a display device provided by an embodiment of the present application.

### DETAILED DESCRIPTION OF THE EMBODIMENT

The technical solutions in the embodiments of the present application are clearly and completely described below in conjunction with the drawings in the embodiments of the present application. Obviously, the embodiments described are only a part of the embodiments of the present application, rather than all the embodiments. Based on the embodiments in the present application, all other embodiments obtained by those skilled in the art without creative works should be deemed as falling within the claims of the present application. Furthermore, it should be understood that specific embodiments described herein are for the purpose of illustration and explanation of the present application only and are not intended to limit the present application. In the present application, the embodiments may be combined with each other, and are not described one by one. In a case that unless stated to the contrary, orientation words, such as “upper” and “lower” are used to generally refer to the upper and lower of the device in actual use or operating condition, specifically drawing directions in the drawings; “inner” and “outer” are for an outline of the device; and words “first”, “second”, “third”, and so on are used for indicative purposes only and do not impose numerical requirements or establish order.

Embodiments of the present application provide a display panel, and a display device, which are described in detail below. It should be noted that the following description order of the embodiments is not limited to the preferred order of the embodiments.

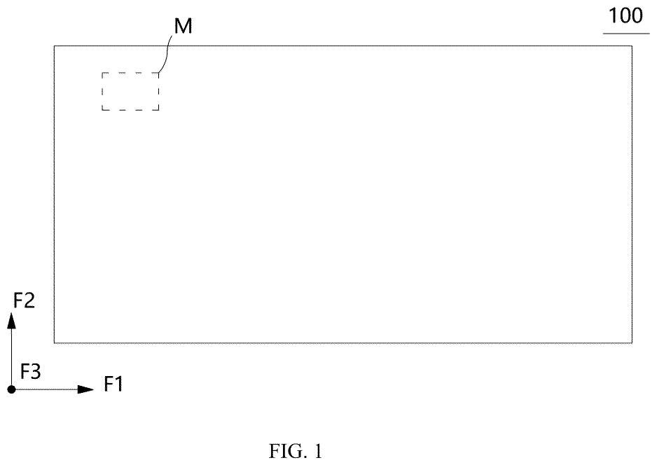

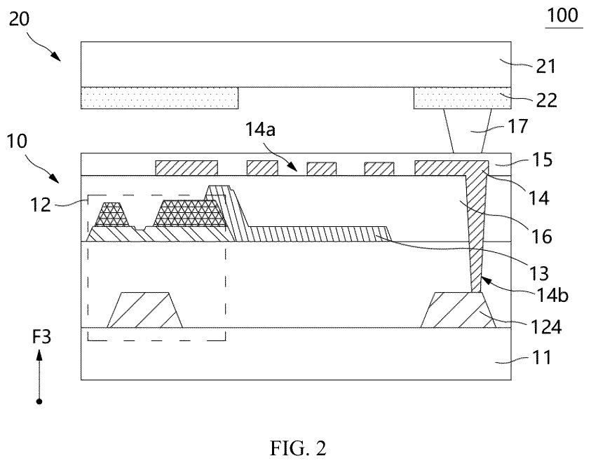

In FIGS. 1 and 2, a first direction F1 may be a direction parallel to one side of the display panel 100 in a plan view, and for example, may be a horizontal direction of the display panel 100. A second direction F2 may be a direction parallel to another side of the display panel 100 in the plan view, and for example, may be a longitudinal direction of the display panel 100. A third direction F3 may be a thickness direction of the display panel 100. Optionally, in some embodiments, the first direction F1 and the second direction F2 may also intersect non-vertically.

The display panel 100 may have a rectangular shape in the plan view, but the embodiments are not limited thereto. In some embodiments, the display panel 100 may have a rectangular shape with vertical corners or rounded corners in the plan view. The display panel 100 may include two short sides arranged in the first direction F1 and two long sides arranged in the second direction F2 in the plan view.

It should be noted that the display panel 100 is a liquid crystal display panel according to the display panel 100 of an embodiment. The display panel 100 includes an array substrate 10, an opposite substrate 20, and liquid crystal molecules disposed between the array substrate 10 and the opposite substrate 20. Optionally, the array substrate 10 may be based on a driving architecture of Fringe Field Switching (FFS) technology, a driving architecture of In-Plane Switching (IPS) technology, a driving architecture of Vertical Alignment (VA) technology, or a driving architecture of Twisted Nematic (TN). Optionally, the opposite substrate 20 may be formed with a color film layer; the opposite substrate 20 may be without a color film layer, for example, the color film layer is formed in the array substrate 10.

Please refer to FIG. 2, the display panel 100 of the embodiment of the present application is described below based on the array substrate 10 adopting the driving architecture of Fringe Field Switching technology.

In some embodiments, the array substrate 10 and the opposite substrate 20 are disposed opposite to each other. The array substrate 10 includes a first substrate 11, a thin-film transistor structure layer 12, a pixel electrode layer 13, a common electrode layer 14, and an alignment film 15. The opposite substrate 20 includes a second substrate 21, and a black matrix layer 22. The black matrix layer 22 is disposed on a side of the second substrate 21 adjacent to the array substrate 10.

It should be noted that the pixel electrode layer 13 and the common electrode layer 14 are arranged in different layers. The pixel electrode layer 13 may be provided in the same layer as one layer of the thin-film transistor structure layer 12, or may be provided in a different layer from the thin-film transistor structure layer 12. In the embodiment of the present application, the film layer position relationship among the pixel electrode layer 13, the common electrode layer 14, and the thin-film transistor structure layer 12 is not limited as long as Fringe Field Switching technology is satisfied.

Hereinafter, embodiments corresponding to the drawings are described in detail, but are not limited thereto.

In FIG. 2, the thin-film transistor structure layer 12 is disposed on the first substrate 11. The pixel electrode layer 13 is disposed on the same layer as data lines (such as 12a and 12b) of the thin-film transistor structure layer 12. An insulating layer 16 covers the pixel electrode layer 13 and the thin-film transistor structure layer 12. The common electrode layer 14 is disposed on a side of the insulating layer 16 away from the first substrate 11. The alignment film 15 is disposed on a side of the common electrode layer 14 away from the first substrate 11.

It should be noted that the thin-film transistor structure layer 12 includes a plurality of thin-film transistors (such as t1 and t2). Types of the plurality of thin-film transistors may include at least one of a top gate type, a bottom gate type, a dual gate type, and a vertical channel type.

In FIG. 2, a source and a drain of the thin-film transistor are directly formed on an active layer. The pixel electrode layer 13 is directly connected to the drain. The common electrode layer 14 is provided with slits 14a, and the slits 14a are configured to assist in adjusting tilting angles of the liquid crystal molecules.

In some embodiments of the present application, the pixel electrode layer 13 is disposed on a side of the common electrode layer 14 away from the first substrate 11, and in this case the pixel electrode layer 13 is provided with slits 14a.

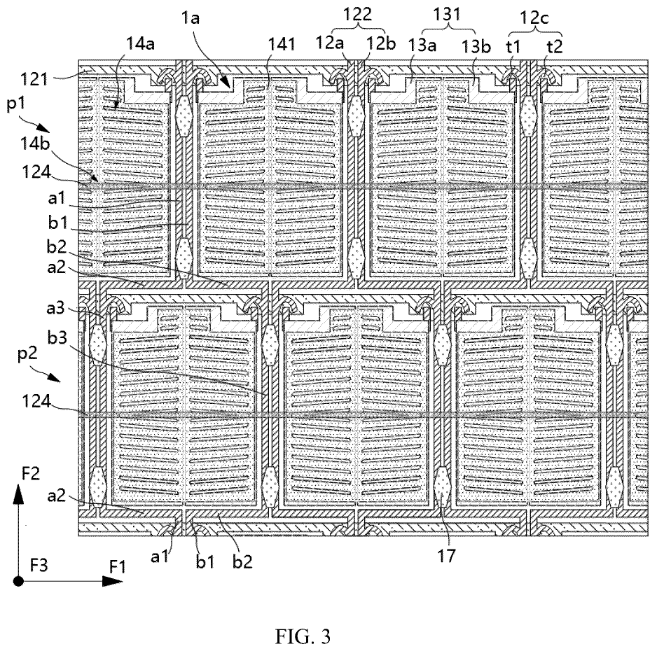

Please refer to FIG. 3, which shows an enlarged schematic view of a portion M in FIG. 1.

The array substrate 10 includes a plurality of scan lines 121, a plurality of data line groups 122, and a plurality of pixel electrode groups 131.

The plurality of data line groups 122 are arranged along the first direction F1. The scan lines 121 extend along the first direction F1, and are arranged along the second direction F2 intersecting with the first direction F1. The plurality of scan lines 121 intersect with the plurality of data line groups 122 to define a plurality of pixel areas 1a.

Each of the pixel electrode groups 131 is correspondingly disposed within one of the pixel areas 1a. The plurality of pixel electrode groups 131 are arranged along the first direction F1 to form pixel rows. The pixel rows include a first pixel row p1 and a second pixel row p2. The first pixel row p1 and the second pixel row p2 are arranged along the second direction F2. In the second direction F2, the pixel electrode group 131 of the first pixel row p1 and one of the pixel electrode groups 131 of the second pixel row p2 are arranged in a stagger layout.

Each of the data line groups 122 includes a first data line 12a and a second data line 12b. Each of the pixel electrode groups 131 includes a first pixel electrode 13a and a second pixel electrode 13b. In the first direction F1, the first pixel electrodes 13a and the second pixel electrodes 13b are arranged alternately, and the first data lines 12a and the second data lines 12b are also arranged alternately. The first data line 12a is connected to the second pixel electrode 13b of the first pixel row p1 and the first pixel electrode 13a of the second pixel row p2. The second data line 12b is connected to the first pixel electrode 13a of the first pixel row p1 and the second pixel electrode 13b of the second pixel row p2.

In the display panel 100 of the embodiments of the present application, a layout of the data line group 122 is adopted, so that there is no data line between the first pixel electrode 13a and the second pixel electrode 13b in the pixel electrode group 131, thereby greatly reducing a distance between the first pixel electrode 13a and the second pixel electrode 13b in the pixel electrode group 131. Furthermore, although the data line is additionally provided between the pixel electrode groups 131, a distance between two data lines (such as 12a and 12b) in the same data line group 122 is less than a distance between the data line and the pixel electrode nearest to the data line in the first direction F1. That is, the distance between the first data line 12a and the second data line 12b is smaller, so that an area of wirings in the first direction F1 is reduced, thereby achieving the effect of improving an aperture ratio.

In some embodiments, the first data line 12a and the second data line 12b may be disposed in different layers. In the first direction F1, the first data line 12a and the second data line 12b may be smaller, and the first data line 12a may even at least partially overlaps with the second data line 12b to further reduce the distance between the first data line 12a and the second data line 12b in the first direction F1, so as to improve the aperture ratio.

In some embodiments of the present application, the array substrate 10 further includes a plurality of thin-film transistor groups 12c. Each of the thin-film transistor groups 12c is disposed between two adjacent ones of the pixel electrode groups 131, and is disposed at a corner area of the two adjacent ones of the pixel electrode groups 131. Each of the thin-film transistor groups 12c includes a first thin-film transistor t1 and a second thin-film transistor t2. Control terminals of the first thin-film transistor t1 and the second thin-film transistor t2 are connected to the scan line 121. An input terminal of the first thin-film transistor t1 is connected to the first data line 12a. An input terminal of the second thin-film transistor t2 is connected to the second data line 12b. In the first pixel row p1, an output terminal of the first thin-film transistor t1 is connected to the second pixel electrode 13b, and an output terminal of the second thin-film transistor t2 is connected to the first pixel electrode 13a. In the second pixel row p2, an output terminal of the first thin-film transistor t1 is connected to the first pixel electrode 13a, and an output terminal of the second thin-film transistor t2 is connected to the second pixel electrode 13b.

The first thin-film transistors t1 and the second thin-film transistors t2 are alternately arranged along the first direction F1 to form rows.

It can be understood that the first thin-film transistor t1 and the second thin-film transistor t2 share a gate in the thin-film transistor group 12c. That is, the first thin-film transistor t1 and the second thin-film transistor t2 gather side by side to form the thin-film transistor group 12c by sharing the gate, so that a total layout area of thin-film transistors is reduced, thereby improving the aperture ratio.

Next, in the first direction F1, the first thin-film transistor t1 and the second thin-film transistor t2 are arranged side by side, so that the layout area in the second direction F2 is further reduced, thereby improving the aperture ratio.

Optionally, in some embodiments of the present application, among each thin-film transistor group 12c, the first thin-film transistor t1 is disposed on a side of the first data line 12a away from the second data line 12b, and the second thin-film transistor t2 is disposed on a side of the second data line 12b away from the first data line 12a.

It can be understood that the data line group 122 is disposed between two thin-film transistors in the thin-film transistor group 12c, so that the distance between the first data line 12a and the second data line 12b in the data line group 122 is reduced, thereby improving the aperture ratio.

Optionally, in some embodiments of the present application, the first data line 12a includes a first wiring portion a1, a second wiring portion a2, and a third wiring portion a3. The first wiring portion a1 is correspondingly disposed in the first pixel row p1, and the third wiring portion a3 is correspondingly disposed in the second pixel row p2. The second wiring portion a2 is correspondingly disposed between the first pixel row p1 and the second pixel row p2, and is connected between the first wiring portion a1 and the third wiring portion a3. The second data line 12b includes a fourth wiring portion b1, a fifth wiring portion b2, and a sixth wiring portion b3. The fourth wiring portion b1 is correspondingly disposed in the first pixel row p1. The sixth wiring portion b3 is correspondingly disposed in the second pixel row p2. The fifth wiring portion b2 is disposed between the first pixel row p1 and the second pixel row p2, and is connected between the fourth wiring portion b1 and the sixth wiring portion b3.

The first wiring portion a1 is connected to the second pixel electrode of the first pixel row p1. The third wiring portion a3 is connected to the first pixel electrode of the second pixel row p2. The fourth wiring portion b1 is connected to the first pixel electrode of the first pixel row p1. The sixth wiring portion b3 is connected to the second pixel electrode of the second pixel row p2.

In the first direction F1, the second wiring portion a2 is disposed on a side of the fifth wiring portion b2. In the second direction F2, the second wiring portion a2 does not overlap with the fifth wiring portion b2.

It can be understood that the second wiring portion a2 and the fifth wiring portion b2 are arranged along the first direction F1, so that a layout area of the second wiring portion a2 and the fifth wiring portion b2 in the second direction F2 may be reduced, thereby improving the aperture ratio.

Optionally, in some embodiments of the present application, the first wiring portion a1, the third wiring portion a3, the fourth wiring portion b1, and the sixth wiring portion b3 each extend along the second direction F2. Both the second wiring portion a2 and the fifth wiring portion b2 extend along the first direction F1. In the first direction F1, the second wiring portion a2 and the fifth wiring portion b2 are aligned with each other.

It can be understood that the second wiring portion a2 and the fifth wiring portion b2 are aligned with each other, and overlap with each other in the first direction F1, so that the layout area of the second wiring portion a2 and the fifth wiring portion b2 in the second direction F2 is further reduced, thereby improving the aperture ratio.

Optionally, in some embodiments of the present application, the display panel 100 further includes a plurality of spacers 17. The spacers 17 are adjacent to the scan lines 121. In the display panel 100 from a top view, the first data line 12a and the second data line 12b in the data line group 122 partially overlap with the spacer 17 in the first direction F1, respectively.

It can be understood that the spacers 17 may be formed on the array substrate 10, or may be formed on the opposite substrate 20. The spacer 17 is disposed between the first data line 12a and the second data line 12b, and extends left and right, so that the spacer 17 partially overlaps with the first data line 12a and the second data line 12b of the data line group 122 at the same time, so as to reduce light-transmitting area occupied by the spacer 17, thereby improving the aperture ratio.

Optionally, in the first direction F1, a width of the spacer 17 is less than or equal to a width of the data line group 122. That is, the spacers 17 are completely arranged in layout areas of the data line groups 122, so as to avoid the spacer 17 from occupying an additional layout area, thereby improving the aperture ratio.

Optionally, in some embodiments of the present application, the spacers 17 are formed on the opposite substrate 20. In the display panel 100 from a top view, the spacers 17 are disposed outside the thin-film transistor group 12c.

It can be understood that since structures of the thin-film transistor groups 12c are relatively uneven, if the spacers 17 are correspondingly disposed at positions of the thin-film transistor groups 12c, a contact area between the spacers 17 and the array substrate 10 is smaller, thereby reducing support performance of the spacers 17. Therefore, the spacers 17 are disposed outside the thin-film transistor groups 12c, so as to improve the contact area between the spacers 17 and the array substrate 10, thereby improving support performance of the spacers 17.

Optionally, in some embodiments of the present application, the spacers 17 are formed on the opposite substrate 20. The array substrate 10 includes the alignment film 15, and an alignment direction of the alignment film 15 is parallel to the first direction F1.

It should be understood that a relative sliding may occur between the spacers 17 and the array substrate 10 under the influence of an external force. Compared with a sliding direction of the spacer 17 perpendicular to the alignment direction of the film 15, in a case that the spacer 17 slides along the left and right directions (the first direction F1), a sliding direction of the spacer 17 is the same as the alignment direction of the alignment film 15, so as to reduce interference of the spacer 17 on the alignment direction of the alignment film 15, thereby reducing risk of red and blue spots.

Optionally, in some embodiments of the present application, each pixel area 1a includes four pixel domain areas. The four pixel domain areas are arranged in an array along the first direction F1 and the second direction F2. In the second direction F2, tilt directions of the liquid crystal molecules of two of the pixel domain areas are different from each other.

The array substrate 10 further includes common wirings 124 extending along the first direction F1. In the display panel 100 from a top view, the common wiring 124 is disposed between two adjacent ones of the pixel domain areas in the second direction F2.

It should be understood that the tilt directions of the liquid crystal molecules of two pixel domain areas are different from each other, so that an arrangement of the liquid crystal molecules at a junction between two pixel domain areas is irregular, thereby easily forming dark textures. Therefore, the common wiring 124 is disposed at the junction between the two pixel domain areas, so that the dark textures can be used to block the common wiring 124, thereby achieving effect of improving the aperture ratio.

In some embodiments of the present application, the plurality of pixel electrode groups 131 are arranged in the pixel electrode layer 13. The array substrate 10 further includes the common electrode layer 14 connected to the common wirings 124. The pixel electrode layer 13 and the common electrode layer 14 are disposed in different layers. The common electrode layer 14 includes a plurality of common electrodes 141. The common electrode 141 is correspondingly disposed in the pixel area 1a. In the display panel 100 from a top view, the common electrode 141 overlaps with the first pixel electrode 13a and the second pixel electrode 13b of the pixel electrode group 131 at the same time.

One of the pixel electrode group 131 and the common electrode 141 adjacent to the opposite substrate 20 is provided with the slits 14a.

As can be seen from FIG. 2, the common electrode 141 is adjacent to the opposite substrate 20, so the common electrode 141 is provided with the slits 14a. In the embodiments of the present application, the common electrode 141 overlaps with two pixel electrodes simultaneously, so that a number of vias 14b through which the common electrodes 141 are connected to the common wirings 124 is reduced.

Optionally, the via 14b is disposed between the first pixel electrode 13a and the second pixel electrode 13b.

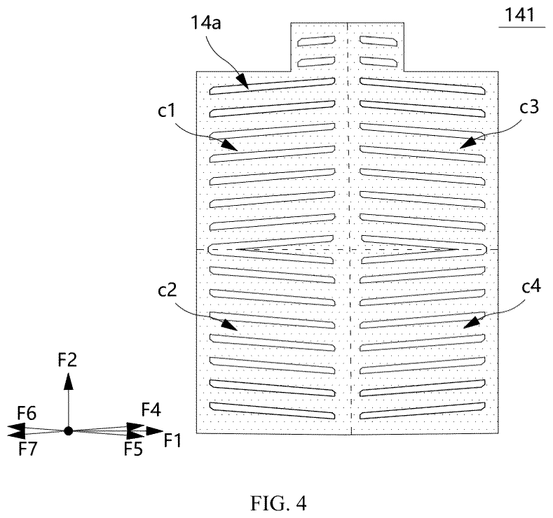

Optionally, please refer to FIG. 4, which shows a schematic structural view of a common electrode 141 in FIG. 3. The four pixel domain area includes a first domain area c1, a second domain area c2, a third domain area c3, and a fourth domain area c4. The first domain area c1 and the second domain area c2 correspond to the first pixel electrode 13a. The third domain area c3 and the fourth domain area c4 correspond to the second pixel electrode 13b.

The first domain area c1 and the second domain area c2 are arranged along the second direction F2. The third domain area c3 and the fourth domain area c4 are arranged along the second direction F2. The first domain area c1 and the third domain area c3 are arranged along the first direction F1. The second domain area c2 and the fourth domain area c4 are arranged along the first direction F1.

Extension directions of the slits 14a intersect the alignment direction (the first direction F1) of the alignment film 15. In the first domain area c1, a plurality of slits 14a extend along the fourth direction F4. In the second domain area c2, a plurality of slits 14a extend along the fifth direction F5. In the third domain area c3, a plurality of slits 14a extend along the sixth direction F6. In the fourth domain area c4, a plurality of slits 14a extend along the seventh direction F7.

It is understood that the pixel area 1a includes four pixel domain areas, so that a viewing angle of the display panel 100 may be expanded.

In some embodiments, positions of the first pixel electrode 13a and the second pixel electrode 13b may be interchanged with each other. For example, the first domain area c1 corresponding to first pixel electrode 13a is interchanged with the third domain area c3 corresponding to the second pixel electrode 13b. The second domain area c2 corresponding to the first pixel electrode 13a is interchanged with the fourth domain area c4 corresponding to the second pixel electrode 13b. The slits 14a corresponding to the domain areas are also interchanged along with the domain areas.

An extension direction of a junction between the first domain area c1 and the second domain area c2 overlaps with an extension direction of a junction between the third domain area c3 and the fourth domain area c4. The common wiring 124 passes through the junction between the first domain area c1 and the second domain area c2 and the junction between the third domain area c3 and the fourth domain area c4.

Optionally, in some embodiments of the present application, in the pixel electrode groups 131 of the display panel 100 from a top view, a pattern formed by all slits 14a defined in the first pixel electrode 13a and a pattern formed by all slits 14a defined in the second pixel electrode 13b are axially symmetrical patterns with each other.

That is, a pattern formed by the slits 14a in the first domain area c1 and a pattern formed by the slits 14a in the third domain area c3 are arranged axially symmetrical with each other. A pattern formed by the slits 14a in the second domain area c2 and a pattern formed by the slits 14a in the fourth domain area c4 are arranged axially symmetrical with each other, thereby improving brightness uniformity of a horizontal viewing angle.

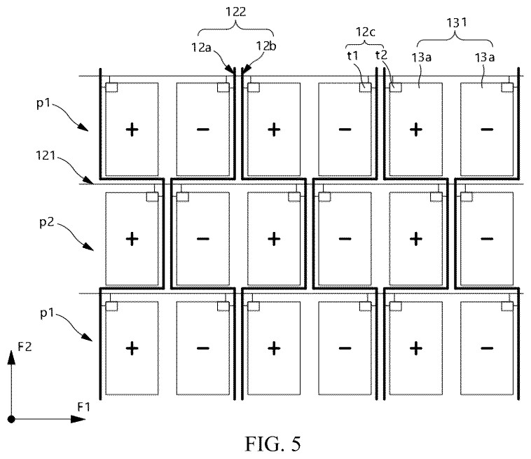

Please refer to FIG. 5, which shows a schematic view of a driving architecture of the display panel 100 of one or more embodiments of the present application. In some embodiments of the present application, in the second direction F2, the first pixel electrodes 13a and the second pixel electrodes 13b are alternately arranged to form pixel columns. In the picture frame, a polarity of a voltage applied to the first data line 12a is opposite to a polarity of a voltage applied to the second data line 12b. For example, a voltage with positive polarity is applied to the first data line 12a, and a voltage with negative polarity is applied to the second data line 12b; or, a voltage with negative polarity is applied to the first data line 12a, and a voltage with positive polarity is applied to the second data line 12b.

It should be noted that since the first data line 12a is connected to the second pixel electrode 13b of the first pixel row p1 and the first pixel electrode 13a of the second pixel row p2, and the second data line 12b is connected to the first pixel electrode 13a of the first pixel row p1 and the second pixel electrode 13b of the second pixel row p2, polarities of voltages applied to the first pixel electrode 13a and the second pixel electrode 13b in the pixel column are the same, and polarities of voltages applied to the first pixel electrode 13a and the second pixel electrode 13b in the pixel row are opposite, so that effect of column flip is achieved, thereby reducing horizontal crosstalk to improve display effect.

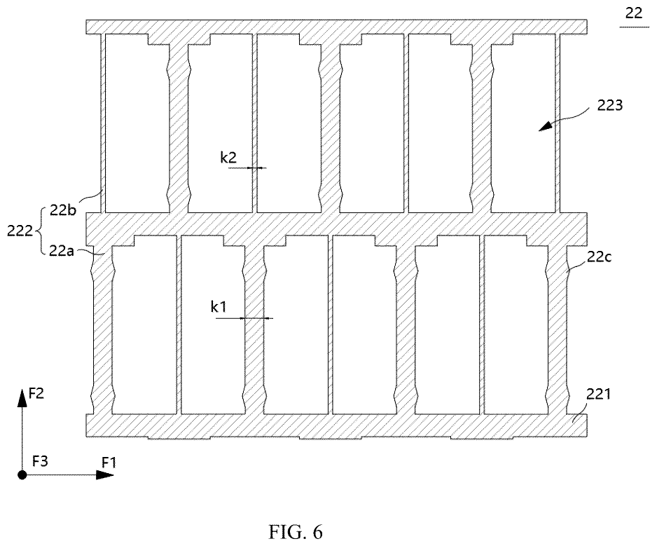

Please refer to FIG. 6, in some embodiments of the present application, the black matrix layer 22 includes a first light-shielding strip 221 and a second light-shielding strip 222. The first light-shielding strip 221 extends along the first direction F1. The second light-shielding strip 222 extends along the second direction F2. A plurality of first light-shielding strips 221 and a plurality of second light-shielding strips 222 are connected in an intersecting manner to define a plurality of openings 223. A portion of the plurality of openings 223 are aligned with the first pixel electrodes 13a, and another portion of the openings 223 of the plurality of openings 223 are aligned with the second pixel electrodes 13b.

The second light-shielding strip 222 includes a first light-shielding portion 22a and a second light-shielding portion 22b. In the first direction F1, a width k1 of the first light-shielding portion 22a is greater than a width k2 of the second light-shielding portion 22b. In the first direction F1, the first light-shielding portions 22a and the second light-shielding portions 22b are arranged alternately. In the second direction F2, the first light-shielding portions 22a and the second light-shielding portions 22b are arranged alternately and are connected to each other.

Further, the first light-shielding portion 22a being wider and the second light-shielding portion 22b being narrower are arranged alternately and are connected to each other in the second direction F2, so that an edge of the second light-shielding strip 222 is non-linear in the second direction F2, thereby reducing the risk of vertical textures in the display panel 100. Optionally, edges of two sides of the second light-shielding strip 222 are non-linear in the second direction F2, so as to further reduce the risk of vertical texture generated by the display panel 100.

In addition, the first light-shielding portion 22a being wider and the second light-shielding portion 22b being narrower are alternately arranged in the first direction F1 and the second direction F2, thereby improving uniformity of display effect.

In conjunction with FIGS. 3 and 6, In the display panel 100 from a top view, the first light-shielding strips 221 covers a portion of the scan lines 121, the second wiring portion a2, and the fifth wiring portion b2. The first light-shielding portion 22a covers a portion of the data line group 122 disposed between two adjacent ones of the pixel electrode groups 131 in the first direction F1. The second light-shielding portion 22b covers an area between the first pixel electrode 13a and the second pixel electrode 13b in the pixel electrode group 131. The second light-shielding portion 22b also covers the via 14b.

It should be noted that the first light-shielding portion 22a covers a portion of the data line group 122 disposed between two adjacent ones of the pixel electrode groups 131 in the first direction F1. The first light-shielding portion 22a in an odd-numbered row may cover the first wiring portion a1 and the fourth wiring portion b1, and the first light-shielding portion 22a in an even-numbered row may cover the third wiring portion a3 and the sixth wiring portion b3.

Further, since the data line group 122 is disposed between two adjacent pixel electrode groups 131 in the first direction F1, so that the distance between two adjacent pixel electrode groups 131 is larger. However, the distance between two pixel electrodes in the pixel electrode group 131 is smaller. Therefore, the width k1 of the first light-shielding portion 22a is greater than the width k2 of the second light-shielding portion 22b to maximize the aperture ratio. Additionally, since the width k1 of the first light-shielding portion 22a is greater than the width k2 of the second light-shielding portion 22b, so that the edge of the second light-shielding strip 222 in the second direction F2 is in in a non-linear shape, thereby reducing the risk of vertical textures generated by the display panel 100 to enhance display uniformity.

In some embodiments of the present application, the third light-shielding portions 22c are connected to either sides of the first light-shielding portion 22a in the first direction F1. In the display panel 100 from a top view, the first light-shielding portion 22a and the third light-shielding portions 22c on both sides thereof as a whole cover the spacer 17.

It can be understood that the first light-shielding portion 22a covers a middle area of the spacer 17, and the third light-shielding portion 22c covers areas of both sides of the spacer 17, so that the first light-shielding portion 22a and the third light-shielding portions 22c cover the spacer 17. Further, since the third light-shielding portions 22c are connected to both sides of the first light-shielding portion 22a, so that the edges of the second light-shielding strip 222 in the second direction F2 is more uneven, thereby reducing the risk of the vertical textures generated by the display panel 100.

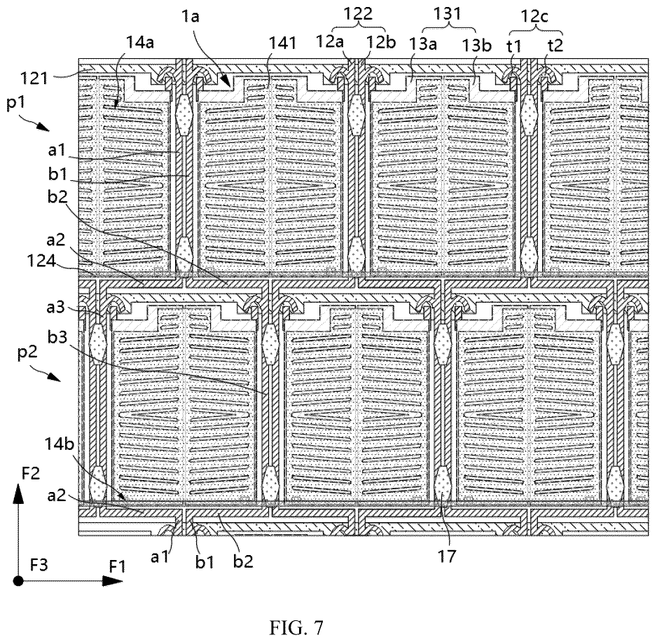

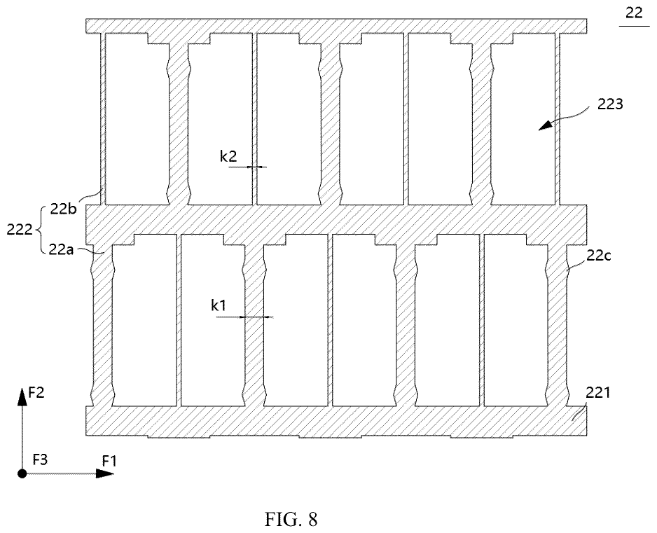

FIG. 7 shows another enlarged schematic view of the portion M in FIG. 1. FIG. 8 is a structural view of a black matrix layer in FIG. 7.

In FIGS. 7 and 8, the contents different from those of the embodiments described above is described in order to avoid redundancy.

Referring to FIGS. 7 and 8, the common wiring 124 and the spacer 17 are disposed between the first pixel row p1 and the second pixel row p2.

In the display panel 100 from a top view, a portion of the plurality of spacers 17 adjacent to the scan line 121 partially overlaps with the common wiring 124. The via 14b at least partially overlaps with the common wiring 124. The first light-shielding strip 221 also covers the common wiring 124. The first light-shielding strip 221 also covers at least a portion of the via 14b.

It can be understood that the common wiring 124 is disposed adjacent to the scan line 121 to improve the aperture ratio. Optionally, in some embodiments, the common wiring 124 may further at least partially overlap with the second wiring portion a2 and the fifth wiring portion b2 to improve the aperture ratio.

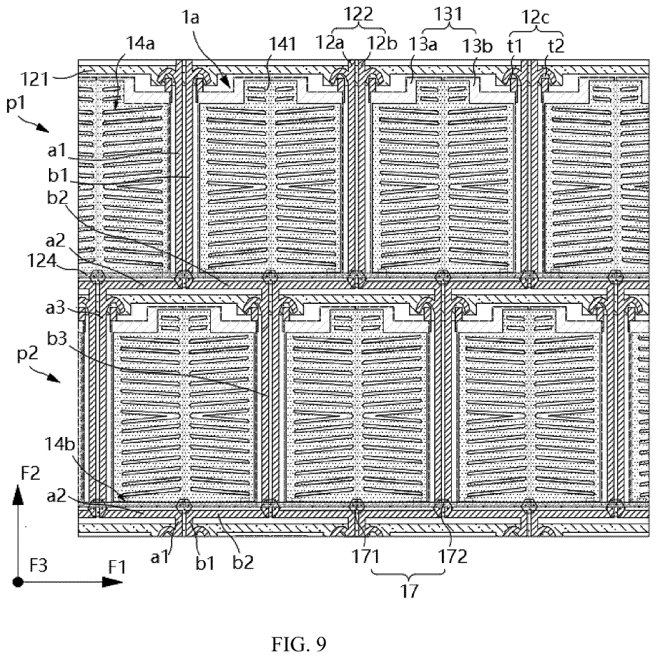

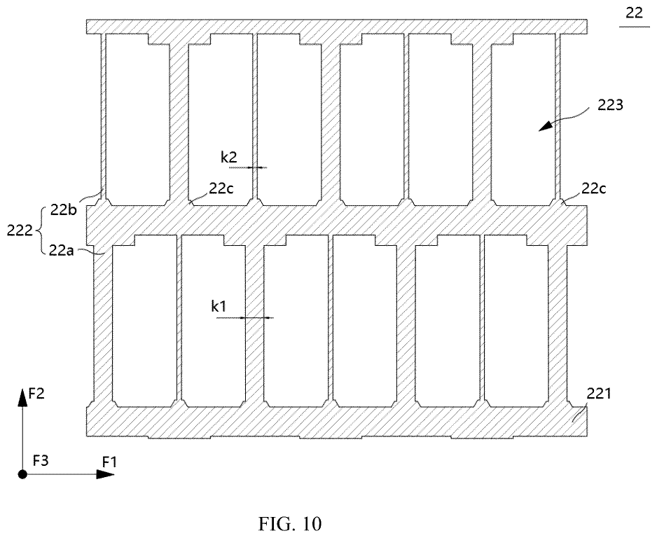

FIG. 9 shows yet another enlarged schematic view of the portion M in FIG. 1. FIG. 10 is a structural view of a black matrix layer in FIG. 9.

In FIGS. 9 and 10, the contents different from those of the embodiments described above is described in order to avoid redundancy.

Referring to FIGS. 9 and 10, in some embodiments of the present application, the common wiring 124 and the spacer 17 are disposed between the first pixel row p1 and the second pixel row p2.

In the display panel 100 from a top view, at least one of the common wiring 124, the scan line 121, and the data line group 122 partially overlap with the spacer 17 at an intersection of the first light-shielding strip 221 and the second light-shielding strip 222.

It can be understood that the spacer 17 is disposed between the first pixel row p1 and the second pixel row p2, and partially overlaps with the wirings of the array substrate 10, so that a light transmitting area occupied by the spacer 17 is reduced, thereby improving the aperture ratio.

The spacer 17 is disposed between the second wiring portion a2 and the fifth wiring portion b2. Therefore, the spacer 17 partially overlaps with the common wiring 124, and the spacer 17 further partially overlaps with the data line group 122.

In some embodiments, spacers 17 away from the thin film transistor group 12c may partially overlap with the scan line 121, so that the spacers 17 away from the thin film transistor group 12c are completely disposed in an layout area between the scan line 121 and the common wiring 124, so an additional layout area occupied by the spacer 17 is avoided, thereby improving the aperture ratio.

In some embodiments, the common wiring 124 may at least partially overlap with the second wiring portion a2 and the fifth wiring portion b2 to improve the aperture ratio.

Optionally, in some embodiments of the present application, the third light-shielding portions 22c are connected to both sides of the intersection of the first light-shielding strip 221 and the second light-shielding strip 222. In the display panel 100 from a top view, the third light-shielding portions 22c as well as a portion of the first light-shielding strip 221 and a portion of the second light-shielding strip 222 connected to the third light-shielding portions 22c, respectively, as a whole cover the spacers 17.

The spacers 17 includes first spacers 171 and second spacers 172. The first spacers 171 and the second spacers 172 are alternately arranged along the first direction F1, and are alternately arranged along the second direction F2.

The first spacers 171 are adjacent to the thin film transistor group 12c, and the second spacers 172 are away from the thin film transistor group 12c. A portion of the second spacer 172 is disposed between the first wiring portion a1 and the fourth wiring portion b1, and partially overlaps with the first wiring portion a1 and the fourth wiring portion b1. A portion of the second spacer 172 is disposed between the third wiring portion a3 and the sixth wiring portion b3, and partially overlaps with the third wiring portion a3 and the sixth wiring portion b3, thereby improving the aperture ratio.

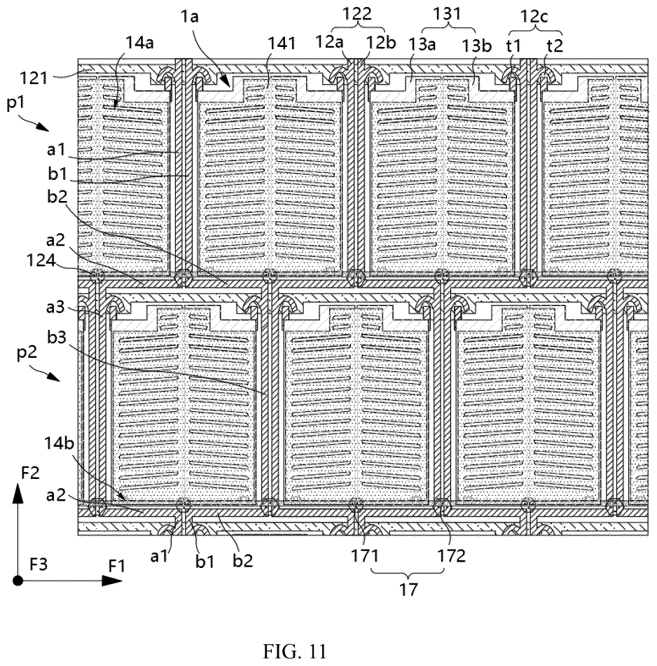

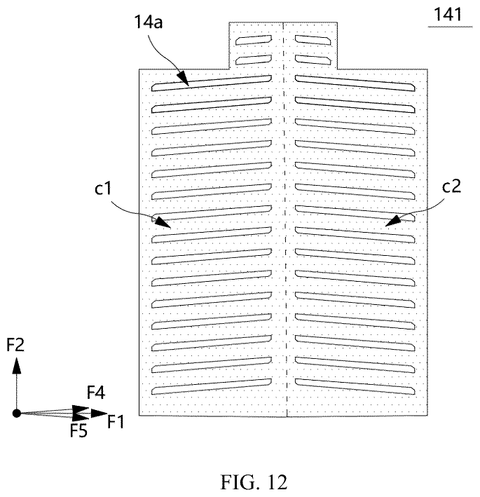

FIG. 11 shows still another enlarged schematic view of the portion M in FIG. 1. FIG. 12 is a schematic structural view of a common electrode in FIG. 11.

Difference between the embodiments shown in FIGS. 11 and 12 and the embodiments shown in FIGS. 9 and 10 is that each pixel area 1a includes dual pixel domain areas. The first pixel electrode 13a and the second pixel electrode 13b correspond to one pixel domain area, respectively.

In FIGS. 11 and 12, the dual pixel domain area includes a first domain area c1 and a second domain area c2. The first domain area c1 corresponds to the first pixel electrode 13a, and the second domain area c2 corresponds to the second pixel electrode 13b. The first domain area c1 and the second domain area c2 are arranged along the first direction F1 and the second direction F2.

Extending directions of the slits 14a intersect with the alignment direction (the first direction F1) of the alignment film 15. In the first domain area c1, a plurality of slits 14a extend along the fourth direction F4. In the second domain area c2, a plurality of slits 14a extend along the fifth direction F5.

A single domain is adopted by both the first pixel electrode 13a and the second pixel electrode 13b, so that a middle dark texture of a pixel electrode with dual domain areas is removed, thereby further improving the aperture ratio and the light transmittance.

In some embodiments of the present application, a pattern formed by the slit 14a in the first domain area c1 and a pattern formed by the slits 14a in the second domain area c2 are arranged axially symmetrical with each other to improve brightness uniformity of the horizontal viewing angle.

Further, the first domain area c1 and the second domain area c2 are arranged along the first direction F1 and the second direction F2, so that four pixel electrodes adjacent to each other are disposed oppositely in pairs to form a pixel repeating unit, so that the pixel repeating unit has four pixel domain areas, thereby expanding a viewing angle of the display panel 100.

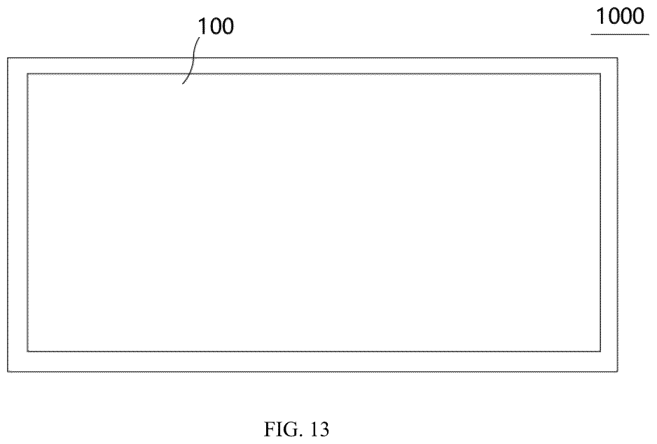

Referring to FIG. 13, FIG. 13 shows a structural view of a display device 1000 provided by an embodiment of the present application. Accordingly, embodiments of the present application further provide a display device 1000 including the display panel 100 described in any one of the embodiments mentioned above.

It should be noted that a structure of the display panel 100 of the display device 1000 is similar to or the same as the structure of the display panel 100 of the embodiments described above. Details thereof are not described herein with reference to the related descriptions of FIGS. 1 to 12.

Optionally, the display device 1000 may be applied to various products, and may be used in various products. The products include, for example, televisions, notebook computers, monitors, billboards, internet of things devices, and portable electronic devices including mobile phones, smartphones, tablet personal computers, mobile communication terminals, electronic notebooks, electronic books, portable multimedia players, navigation, and ultra-mobile personal computers.

Further, according to some embodiments, the display device 1000 may be applied to a wearable device, and may be used in the wearable device. The wearable device includes a smart watch, a watch phone, a glasses-type display, and a head-mounted display (HMD). Further, according to some embodiments, the display device 1000 may be applied to an instrument panel of an automobile, a display screen for a center instrument panel of an automobile or a central information display (CID) disposed on the instrument panel, an interior display mirror instead of a side mirror of an automobile, and a display panel of an entertainment system disposed on a back surface of a front seat for passengers at rear seat in an automobile.

In the display device 1000 of the embodiments of the present application, a layout of the data line group 122 is adopted, so that there is no data line between the first pixel electrode 13a and the second pixel electrode 13b in the pixel electrode group 131, thereby greatly reducing a distance between the first pixel electrode 13a and the second pixel electrode 13b in the pixel electrode group 131. Furthermore, although the data line is additionally provided between the pixel electrode groups 131, the distance between the first data line 12a and the second data line 12b is smaller, thereby the area of wirings in the first direction F1 is reduced, thereby achieving the effect of improving an aperture ratio.

The above is a detailed introduction to the display panel and the display device provided by the embodiments of the present application. Specific examples are used in this article to illustrate principles and implementation methods of the present application. The description of the above embodiments is only used to help understand technical solutions and core ideas of the present application. Meanwhile, those skilled in the art may change the specific embodiments and the scope of application according to the ideas of the present application. In summary, the contents of the specification should not be construed as limiting the present application.

What is claimed is:

1. A display panel, comprising an array substrate and an opposite substrate disposed opposite to the array substrate, the array substrate comprising:
a plurality of data line groups, arranged along a first direction;
a plurality of scan lines, wherein each of the scan lines extends along the first direction, the plurality of scan lines are arranged along a second direction intersecting with the first direction, wherein the plurality of scan lines intersect with the plurality of data line groups to define a plurality of pixel areas; and
a plurality of pixel electrode groups, wherein each of the pixel electrode groups is correspondingly disposed within one of the pixel areas, and the plurality of pixel electrode groups are arranged along the first direction to form pixel rows; the pixel rows comprises a first pixel row and a second pixel row arranged along the second direction; and along the second direction, one of the pixel electrode groups of the first pixel row and one of the pixel electrode groups of the second pixel row are arranged in a stagger layout;
wherein each of the data line groups comprises a first data line and a second data line, and each of the pixel electrode groups comprises a first pixel electrode and a second pixel electrode, the plurality of pixel electrode groups comprises a plurality of the first pixel electrodes and a plurality of the second pixel electrodes;
along the first direction, the first pixel electrodes and the second pixel electrodes are arranged alternately, and the first data lines and the second data lines are arranged alternately;
the first data line is connected to the second pixel electrode of the first pixel row and the first pixel electrode of the second pixel row, and the second data line is connected to the first pixel electrode of the first pixel row and the second pixel electrode of the second pixel row.

2. The display panel according to claim 1, wherein the first data line comprises a first wiring portion, a second wiring portion, and a third wiring portion; the first wiring portion is correspondingly disposed in the first pixel row, and is connected to the second pixel electrode of the first pixel row; the third wiring portion is correspondingly disposed in the second pixel row, and is connected to the first pixel electrode of the second pixel row; and the second wiring portion is correspondingly disposed between the first pixel row and second pixel row, and is connected between the first wiring portion and third wiring portion;
wherein the second data line comprises a fourth wiring portion, a fifth wiring portion, and a sixth wiring portion; the fourth wiring portion is correspondingly disposed in the first pixel row, and is connected to the first pixel electrode of the first pixel row; the sixth wiring portion is correspondingly disposed in the second pixel row, and is connected to the second pixel electrode of the second pixel row; and the fifth wiring portion is disposed between the first pixel row and the second pixel row, and is connected between the fourth wiring portion and the sixth wiring portion; and
wherein in the first direction, the second wiring portion is disposed on a side of the fifth wiring portion; and along the second direction, the second wiring portion does not overlap with the fifth wiring portion.

3. The display panel according to claim 2, wherein the first wiring portion, the third wiring portion, the fourth wiring portion, and the sixth wiring portion each extend along the second direction, and the second wiring portion and the fifth wiring portion each extend along the first direction; and
wherein along the first direction, the second wiring portion is aligned with the fifth wiring portion.

4. The display panel according to claim 3, wherein the opposite substrate comprises a black matrix layer, and the black matrix layer comprises a plurality of first light-shielding strips and a plurality of second light-shielding strips;
the plurality of first light-shielding strips extend along the first direction, the plurality of second light-shielding strips extend along the second direction, and the plurality of first light-shielding strips are connected to the plurality of second light-shielding strips in an intersecting manner to define a plurality of openings; and a portion of the plurality of openings are aligned with the first pixel electrodes, and another portion of the plurality of openings are aligned with the second pixel electrodes; and
the second light-shielding strip comprises a first light-shielding portion and a second light-shielding portion; in the first direction, a width of the first light-shielding portion is greater than a width of the second light-shielding portion; in the first direction, a plurality of the first light-shielding portions and a plurality of the second light-shielding portions are arranged alternately; and in the second direction, the plurality of first light-shielding portions and the plurality of second light-shielding portions are alternately connected; and
wherein in the display panel from a top view, the first light-shielding strip covers a portion of the scan lines, the second wiring portion, and the fifth wiring portion; the first light-shielding portion covers a portion of the data line groups disposed between two adjacent ones of the pixel electrode groups in the first direction; and the second light-shielding portion covers an area between the first pixel electrode and second pixel electrode of each of the pixel electrode groups.

5. The display panel according to claim 4, wherein the array substrate further comprises a plurality of thin-film transistor groups, and each of the thin-film transistor groups is disposed between two adjacent ones of the pixel electrode groups and is disposed at a corner area of the two adjacent ones of the pixel electrode groups;
wherein each of thin-film transistor groups comprises a first thin-film transistor and a second thin-film transistor; a control terminal of the first thin-film transistor and a control terminal of the second thin-film transistor are connected to one of the scan lines; an input terminal of the first thin-film transistor is connected to the first data line, and an input terminal of the second thin-film transistor is connected to the second data line;
wherein in the first pixel row, an output terminal of the first thin-film transistor is connected to the second pixel electrode, and an output terminal of the second thin-film transistor is connected to the first pixel electrode; and in the second pixel row, an output terminal of the first thin-film transistor is connected to the first pixel electrode, and an output terminal of the second thin-film transistor is connected to the second pixel electrode; and
wherein a plurality of the first thin-film transistors and a plurality of the second thin-film transistors are alternately in rows arranged along the first direction; in each of the thin-film transistor groups, the first thin-film transistor is disposed on a side of the first data line away from the second data line, and the second thin-film transistor is disposed on a side of the second data line away from the first data line.

6. The display panel according to claim 5, wherein the display panel further comprises a plurality of spacers, and each of the spacers is disposed at an intersection of the first light-shielding strip and the second light-shielding strip;
wherein the array substrate further comprises common wirings extending along the first direction, and the common wirings and the spacers are disposed between the first pixel row and the second pixel row; and
wherein in the display panel from a top view, at least one of the common wirings, the scan lines, and the data line groups partially overlaps with the spacers.

7. The display panel according to claim 6, wherein a third light-shielding portion is connected to either side of the intersection of the first light-shielding strip and the second light-shielding strip; and
in the display panel from a top view, a portion of the first light-shielding strip and a portion of the second light-shielding strip connected to the third light-shielding portion, respectively as well as the third light-shielding portion, as a whole correspondingly cover one of the spacers.

8. The display panel according to claim 7, wherein each of the pixel areas comprises dual pixel domain areas, and the first pixel electrode and the second pixel electrode correspond to one of the dual pixel domain areas, respectively.

9. The display panel according to claim 5, wherein the display panel further comprises a plurality of spacers adjacent to the scan lines; and
wherein in the display panel from a top view, in the first direction, the first data line and the second data line of a same one the data line groups partially overlap with a same one of the spacers, respectively.

10. The display panel according to claim 9, wherein each of the pixel areas comprises four pixel domain areas arranged in an array along the first direction and the second direction; and tilt directions of liquid crystal molecules of two of the pixel domain areas in the second direction are different from each other; and
wherein the array substrate further comprises common wirings extending along the first direction, and in the display panel from a top view, each of the common wirings is disposed between two adjacent ones of the pixel domain areas in the second direction.

11. The display panel according to claim 9, wherein the array substrate further comprises common wirings extending along the first direction, and the common wirings and the spacers are disposed between the first pixel row and second pixel row; and
wherein in the display panel from a top view, a portion of the plurality of spacers adjacent to the scan lines partially overlap with the common wirings, and the first light-shielding strips cover the common wirings.

12. The display panel according to claim 9, wherein in the first direction, a third light-shielding portion is connected to either side of each of the first light-shielding portions; and
wherein in the display panel from a top view, each of the first light-shielding portions and the third light-shielding portions on both sides thereof as a whole cover one of the spacers.

13. The display panel according to claim 6, wherein the spacers are formed on the opposite substrate, and in the display panel from a top view, the spacers are disposed outside the thin-film transistor groups.

14. The display panel according to claim 6, wherein the spacers are disposed on the opposite substrate, the array substrate comprises an alignment film, and an alignment direction of the of the alignment film is parallel to the first direction.

15. The display panel according to claim 14, wherein the plurality of pixel electrode groups are arranged in the pixel electrode layer;
the array substrate further comprises a common electrode layer connected to the common wirings, and the pixel electrode layer and the common electrode layer are arranged in different layers; the common electrode layer comprises a plurality of common electrodes, and each of the common electrodes is correspondingly disposed within one of the pixel areas;
in the display panel from a top view, one of the common electrodes overlaps with the first pixel electrode and the second pixel electrode of a same one of the pixel electrode groups;
ones of the pixel electrode groups and the common electrodes that are closer to the opposite substrate are provided with slits;
in the pixel electrode group of the display panel from a top view, a pattern formed by all slits defined in the first pixel electrode and a pattern formed by all slits defined in the second pixel electrode are axially symmetrical patterns with each other.

16. The display panel according to claim 5, wherein the first pixel electrodes and the second pixel electrodes are alternately in pixel columns arranged in the second direction, and the pixel columns are arranged along the first direction; and wherein a polarity of a voltage applied to the first data line is opposite to a polarity of a voltage applied to the second data line in one frame.

17. A display device, comprising a display panel, the display panel comprising an array substrate and an opposite substrate disposed opposite to the array substrate, the array substrate comprising:
a plurality of data line groups, arranged along a first direction;
a plurality of scan lines, extending along the first direction and arranged along a second direction intersecting with the first direction, wherein the plurality of scan lines intersect with the plurality of data line groups to define a plurality of pixel areas; and
a plurality of pixel electrode groups, wherein each of the pixel electrode groups is correspondingly disposed within one of the pixel areas, and the plurality of pixel electrode groups are arranged along the first direction to form pixel rows; the pixel rows comprises a first pixel row and a second pixel row arranged along the second direction; and along the second direction, one of the pixel electrode groups of the first pixel row and one of the pixel electrode groups of the second pixel row are arranged in a stagger layout;
wherein each of the data line groups comprises a first data line and a second data line, and each of the pixel electrode groups comprises a first pixel electrode and a second pixel electrode, the plurality of pixel electrode groups comprises a plurality of the first pixel electrodes and a plurality of the second pixel electrodes;
along the first direction, the first pixel electrodes and the second pixel electrodes are arranged alternately, and the first data lines and the second data lines are arranged alternately;
the first data line is connected to the second pixel electrode of the first pixel row and the first pixel electrode of the second pixel row, and the second data line is connected to the first pixel electrode of the first pixel row and the second pixel electrode of the second pixel row.

18. The display device according to claim 17, wherein the first data line comprises a first wiring portion, a second wiring portion, and a third wiring portion; the first wiring portion is correspondingly disposed in the first pixel row, and is connected to the second pixel electrode of the first pixel row; the third wiring portion is correspondingly disposed in the second pixel row, and is connected to the first pixel electrode of the second pixel row; and the second wiring portion is correspondingly disposed between the first pixel row and second pixel row, and is connected between the first wiring portion and third wiring portion;
wherein the second data line comprises a fourth wiring portion, a fifth wiring portion, and a sixth wiring portion; the fourth wiring portion is correspondingly disposed in the first pixel row, and is connected to the first pixel electrode of the first pixel row; the sixth wiring portion is correspondingly disposed in the second pixel row, and is connected to the second pixel electrode of the second pixel row; and the fifth wiring portion is disposed between the first pixel row and the second pixel row, and is connected between the fourth wiring portion and the sixth wiring portion; and
wherein in the first direction, the second wiring portion is disposed on a side of the fifth wiring portion; and along the second direction, the second wiring portion does not overlap with the fifth wiring portion.

19. The display device according to claim 18, wherein the first wiring portion, the third wiring portion, the fourth wiring portion, and the sixth wiring portion each extend along the second direction, and the second wiring portion and the fifth wiring portion each extend along the first direction; and
wherein along the first direction, the second wiring portion is aligned with the fifth wiring portion.

20. The display device according to claim 19, wherein the opposite substrate comprises a black matrix layer, and the black matrix layer comprises a plurality of first light-shielding strips and a plurality of second light-shielding strips;
the plurality of first light-shielding strips extend along the first direction, the plurality of second light-shielding strips extend along the second direction, and the plurality of first light-shielding strips are connected to the plurality of second light-shielding strips in an intersecting manner to define a plurality of openings; and a portion of the plurality of openings are aligned with the first pixel electrodes, and another portion of the plurality of openings are aligned with the second pixel electrodes; and
the second light-shielding strip comprises a first light-shielding portion and a second light-shielding portion; in the first direction, a width of the first light-shielding portion is greater than a width of the second light-shielding portion; in the first direction, a plurality of the first light-shielding portions and a plurality of the second light-shielding portions are arranged alternately; and in the second direction, the plurality of first light-shielding portions and the plurality of second light-shielding portions are alternately connected; and
wherein in the display panel from a top view, the first light-shielding strip covers a portion of the scan lines, the second wiring portion, and the fifth wiring portion; the first light-shielding portion covers a portion of the data line groups disposed between two adjacent ones of the pixel electrode groups in the first direction; and the second light-shielding portion covers an area between the first pixel electrode and second pixel electrode of each of the pixel electrode groups.
